(19) United States
(12) Patent Application Publication
(10) Pub. No.: US 2024/0282731 A1
(43) Pub. Date: Aug. 22, 2024

(54) HYBRID BONDING FOR SEMICONDUCTOR DEVICE ASSEMBLIES

(71) Applicant: Micron Technology, Inc., Boise, ID (US)

(72) Inventors: Bharat Bhushan, Taichung (TW); Wei Zhou, Boise, ID (US); Debjit Datta, Taichung (TW); Chaiyanan Kulchaisit, Hiroshima (JP); Kyle K. Kirby, Eagle, ID (US); Akshay N. Singh, Boise, ID (US)

(21) Appl. No.: 18/406,068

(22) Filed: Jan. 5, 2024

Related U.S. Application Data
(60) Provisional application No. 63/447,600, filed on Feb. 22, 2023.

(51) Int. Cl. H01L 23/00; H01L 21/56; H01L 23/29

(52) U.S. Cl. CPC H01L 24/08; H01L 21/56; H01L 23/295; H01L 24/05; H01L 24/13; H01L 24/80; H01L 2224/02379; H01L 2224/05647; H01L 2224/05681; H01L 2224/08145; H01L 2224/13111; H01L 2224/13139; H01L 2224/13147; H01L 2224/13155; H01L 2224/80895; H01L 2224/80896

(57) ABSTRACT

A semiconductor device assembly, including a semiconductor die having a frontside surface, a first plurality of bond pads at the frontside surface and a first dielectric layer at the frontside surface; and an interface die having a frontside surface and a backside surface, the interface die including a second plurality of bond pads and a second dielectric layer disposed on the backside surface of the interface die, a third dielectric layer disposed on the frontside surface of the interface die, wherein the third dielectric layer includes a mechanically altered surface opposite the frontside surface of the interface die, and a redistribution layer disposed on the third dielectric layer and above the frontside surface of the interface die, wherein hybrid bonds are disposed between the frontside surface of the semiconductor die and the backside surface of the interface die.

### CROSS-REFERENCE TO RELATED APPLICATION(S)

The present application claims priority to U.S. Provisional Patent Application No. 63/447,600, filed Feb. 22, 2023, the disclosure of which is incorporated herein by reference in its entirety.

### TECHNICAL FIELD

The present disclosure generally relates to semiconductor devices, and more particularly relates to hybrid bonding for semiconductor device assemblies.

### BACKGROUND

Semiconductor packages typically include a semiconductor die (e.g., memory chip, microprocessor chip, imager chip) mounted on a substrate or a semiconductor wafer and encased in a protective covering (e.g., an encapsulating material). The semiconductor die may include functional features, such as memory cells, processor circuits, or imager devices, as well as bond pads electrically connected to the functional features. The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies. Hybrid bonding (also refers as fusion bonding or direct bonding) describes a bonding process with minimal intermediate layers between semiconductor dies and semiconductor wafer in the CoW process. The hybrid bonding technique helps semiconductor die manufacturers meet demands for a reduction in the volume occupied by semiconductor die assemblies.

### BRIEF DESCRIPTION OF THE DRAWINGS

FIGS. 1A through 1D illustrate stages of a process for semiconductor dies in accordance with embodiments of the present technology.

FIGS. 2A through 2E illustrate stages of a process for a semiconductor wafer in accordance with embodiments of the present technology.

FIG. 3A through 3C illustrate stages of a process for forming semiconductor die assemblies in accordance with embodiments of the present technology.

FIG. 4 depicts a diagram of a semiconductor wafer with semiconductor dies attached thereon in accordance with embodiments of the present technology.

FIG. 5 is a flow chart illustrating a method of processing semiconductor device assemblies according to embodiments of the present technology.

FIG. 6 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

CoW assembly is a promising technology for high density package application to overcome the limitations of Wafer-to-Wafer (WoW) bonding and improve die stacking process yield and bonding placement accuracy. Conventional CoW assembly includes a frontside to backside (F2B) attachment, i.e., attaching a frontside surface of a semiconductor die or stacks of semiconductor dies on a backside surface of a semiconductor wafer through hybrid bonding, wherein the semiconductor wafer includes macro bumps and has been attached on a carrier wafer through adhesive materials before the CoW assembly. Hybrid bonding processes rely on chemical bonds and interactions between interfacing surfaces of the semiconductor dies and the interface wafer. For example, intermolecular interactions including van der Waals forces, hydrogen bonds, and strong covalent bonds can be formed in the hybrid bonding process to join metal-metal interfaces as well as dielectric-dielectric surfaces at high temperatures and/or compression pressures. Further, the bonding interface between the semiconductor dies and semiconductor wafer may be affected by thermal cycles, e.g., anneal temperatures, that are applied during the hybrid bonding process.

In general, the conventional CoW assembly processes utilize a post bond thermal anneal process to achieve a gap free metal-metal bonding between the bond pads of the semiconductor die or stacking of semiconductor dies and the interface wafer. One of the challenges for the conventional CoW assembly is that the post bond anneal temperature is limited and can not form a conjoined metal-metal bonding interface between the bond pads. Further, macro bumps included in the semiconductor wafer may contain solder materials which may melt at a temperature that is higher than 260° C. and that lasts for longer than 70 seconds. In addition, adhesive material used to attach the semiconductor wafer on the carrier wafer may have a glass transition temperature (Tg) of around 300° C., above which the adhesive material presents degraded physical strength and stiffness. The degraded adhesion between the semiconductor wafer and carrier wafer may cause the semiconductor wafer backside bond pad polishing variation or even hard pad chemical mechanical planarization (CMP) chipping risks during the CoW assembly processes. Moreover, the limited temperature of post bond anneal thermal cycles, e.g., 300° C., is not high enough to form a gap/void free metal-metal bonding interface in the CoW assembly and may degrade device performance of the assembled semiconductor die or stacking of semiconductor dies.

To address these challenges and others, the present technology applies a redistribution layer (RDL)/micro bump last process flow, in which the RDL layers and micro bumps structures are fabricated after attaching the semiconductor die or a stacking of semiconductor dies to the interface wafer. In this scheme, the semiconductor wafer is attached to a carrier wafer through fusion bonding techniques before the semiconductor die being attached to the interface wafer. The fusion bonded semiconductor wafer on the carrier wafer can provide a more rigid mechanical strength during the CoW assembly processes. Specifically, the post bond anneal temperature limitations caused by low Tg temperature of adhesive materials for carrier wafer bonding and macro bump solder melting risk are lifted, allowing higher temperature, e.g., at around 300° C. or higher, semiconductor wafer backside processes including dielectric layers depositions. In the present technique, the semiconductor die or stacking of semiconductor dies can be attached to the semiconductor wafer at a higher temperature, e.g., at around 300° C. or higher, to form hybrid bonds at the interface therebetween. The carrier wafer of the semiconductor wafer can be removed by a grinding process after the hybrid bonding. Further, this integration scheme allows a higher temperature, e.g., at around 350° C., post bond anneal process for a metal-metal gap closure for gap/void free metal-metal bonds in the CoW assembly.

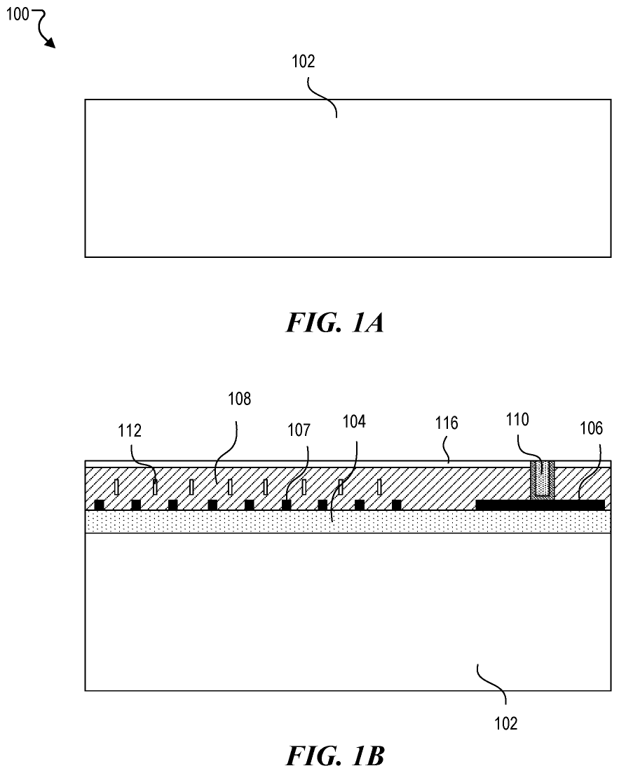

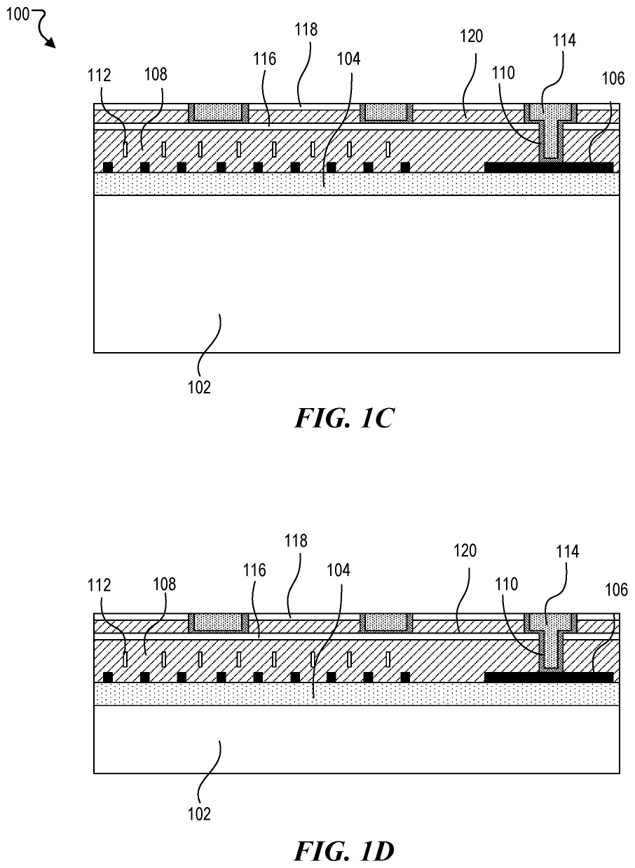

FIGS. 1A through 1D illustrate stages of a process for a semiconductor die 100 in accordance with embodiments of the present technology. FIG. 1A illustrate a cross-sectional view of a substrate 102 provided for various processes upon completing the semiconductor die 100. For example, FIG. 1A shows the substrate 102 having a frontside and a backside opposite to the frontside. The frontside of the substrate 102 may include integrated circuits (e.g., a memory array, peripheral circuitry operatively coupled to the memory array, etc.). In addition, the substrate 102 of the semiconductor die 100 can be electrically coupled to additional semiconductor dies (not shown) disposed above or adjacent to the semiconductor die 100, such that the semiconductor die 100 interfaces between the additional semiconductor dies and a host device. The substrate 102 may be made of materials including silicon, silicon germanium, glass, or any combination thereof.

FIG. 1B illustrates a cross-sectional view of the semiconductor die 100 after a back-end-of-line (BEOL) structure 104, air gaps 112, a probe pad 106, and a via 110 formed on the frontside of the substrate 102. In some embodiments, the BEOL structure 104 including metallization layers and dielectric isolation layers can be fabricated on the substrate 102. The BEOL structure 104 may include metallic materials (e.g., copper and/or aluminum) and dielectric materials (e.g., silicon oxide, and/or silicon nitride). Individual devices such as transistors, capacitors, and/or resistors disposed on the frontside of the substrate 102 can be interconnected through the BEOL structure 104 and further electrically connected with I/O of the semiconductor die 100.

In some embodiments, the probe pad 106 and plurality of conductive lines 107 can be fabricated above the BEOL structure 104 of the semiconductor die 100. The probe pad 106 and the plurality of conductive lines 107 may have a thickness ranging from 200 nm to 1 um and are formed from a suitable conductive metal such as copper, aluminum, tungsten, cobalt, nickel, or any other suitable conductive materials using an additive process, including but not limited to, plating, depositing, or any other suitable method of manufacturing. After the probe pad 106 and plurality of conductive lines 107 have been patterned, a dielectric layer 108 may be formed above the BEOL structure 104 and encapsulate the probe pad 106 and the plurality of conductive lines 107. The dielectric layer 108 may have a thickness ranging from 1 um to 5 um and be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. In addition, the dielectric layer 108 may be processed by a deposition technique at temperatures ranging from 200° C. to 400° C. Depending on dimensions and pitches of the plurality of conductive lines 107, one or more airgaps 112 may be present in the dielectric layer 108. Thereafter, a dielectric layer 116 may be formed on the dielectric layer 108. The dielectric layer 116 may be deposited at a high temperature around 350° C. and made of materials such as silicon carbon nitride (SiCN), silicon boron carbonitride (SiBCN), or any combination thereof. In addition, the dielectric layer 116 may have a thickness ranging from 50 nm to 300 nm.

In some embodiments and after forming the dielectric layer 116, a via 110 may be formed within the dielectric layer 108 and electrically coupled to the probe pad 106. The via 110 may be processed by patterning the dielectric layer 116 and the dielectric layer 108, and then filling the patterned regions with liner materials and conductive materials. The via 110 can be made of copper using a suitable process such as plating or depositing.

FIG. 1C illustrates a cross-sectional view of the semiconductor die 100 after forming a dielectric layer 120, a dielectric layer 118 and bond pads 114. As shown, the dielectric layer 120 can be fabricated above the dielectric layer 116. In some embodiments, the dielectric layer 120 can be made of silicon oxide by a high temperature process at 300° C. or above. In addition, the dielectric layer 120 may have a thickness ranging from 1 um to 5 um. The dielectric layer 118 can be fabricated above the dielectric layer 120 with a thickness ranging from 20 nm to 200 nm. The dielectric layer 118 can be made of SiCN by a high temperature process at 300° C. or above. Subsequently, bond pads 114 are formed in the dielectric layers 118 and 120. Each of the bond pads 114 may include a conductive liner (e.g., TaN) and a metal filler (e.g., copper). The bond pads 114 may have a thickness ranging from 1 um to 5 um. As shown, one of the bond pads 114 and the via 110 may be connected to each other and include a same liner material and a same metal filler material. Specifically, the one of the bond pads 114 can be electrically coupled to the probe pad 106 through the via 110.

FIG. 1D illustrates a cross-sectional view of the semiconductor die 100 after wafer thinning and stealth dicing. For example, after the frontside processes are completed, the backside surface of the substrate 102 can be further thinned by a suitable technique such as wafer back grinding to remove the bulk of excess substrate/wafer thickness. After wafer thinning, the semiconductor die 100 can be cut from a wafer by a stealth dicing process using a laser technique.

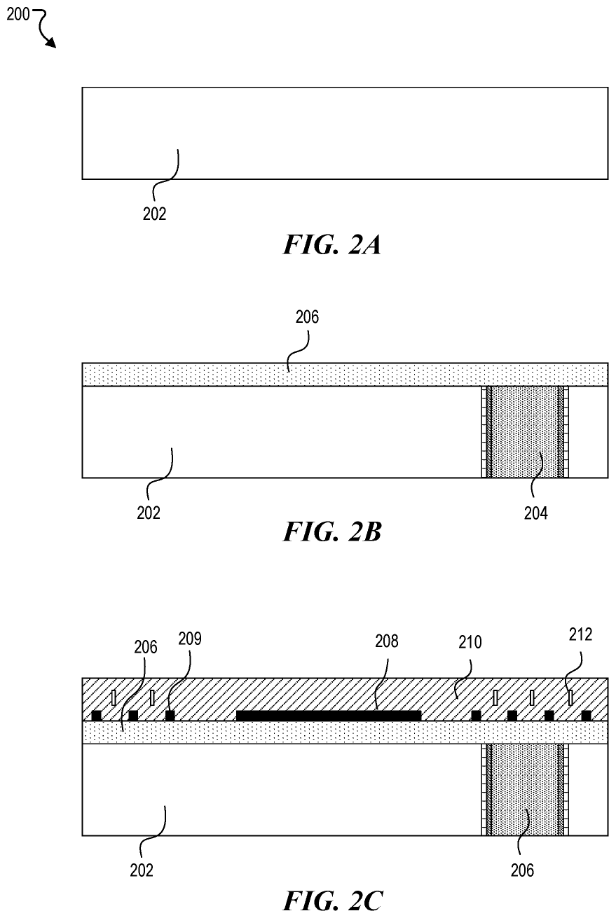

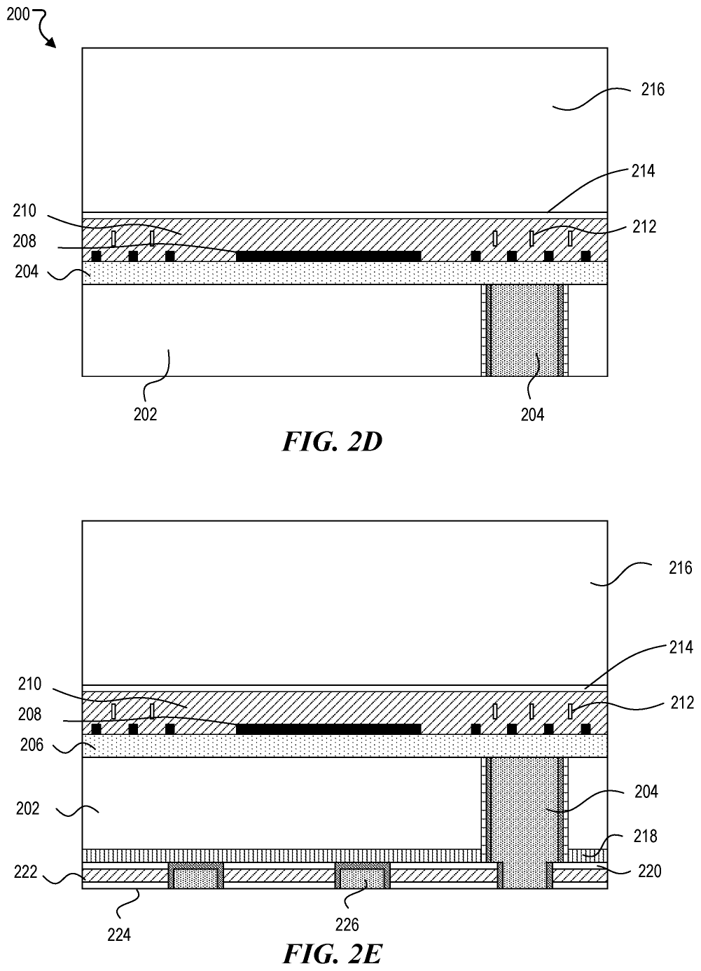

FIGS. 2A through 2E illustrate stages of a process for a semiconductor wafer (or interface wafer) 200 in accordance with embodiments of the present technology. FIG. 2A illustrates an interface substrate 202 having a frontside and a backside opposite to the frontside. The frontside of the interface substrate 202 may include integrated circuits (e.g., a logic circuit, peripheral circuitry operatively coupled to the logic circuit, etc.). In addition, the interface substrate 202 of the semiconductor wafer 200 can be used for wafer level packaging, e.g., attaching semiconductor dies or stacks of semiconductor dies thereon. Attaching semiconductor dies 100 to the semiconductor wafer 200 can also be referred to as CoW. The interface substrate 202 may be made of materials including silicon, silicon germanium, glass, or any combination thereof. In some embodiments, the semiconductor wafer 200 may be an ultra-thin logic wafer, e.g., having a thickness of the interface substrate 202 close to or less than 50 um.

FIG. 2B illustrates a cross-sectional view of the semiconductor wafer 200 after TSV 204 and a BEOL structure 206 are formed on the frontside of the interface substrate 202. Here, the TSV 204 may be formed in a via-middle (VM) approach, e.g., fabricated after the interface substrate 200 preparation and before the BEOL 206 process. In some embodiments, the TSV 204 can be formed from the backside of the interface substrate 202 by etching the backside of the substrate 102. Then the TSV 204 can be filled with conductive liner materials such as TaN and a metal filler material that can be made of copper, tungsten, molybdenum, nickel, titanium, tantalum, platinum, silver, gold, ruthenium, iridium, rhenium, rhodium, or alloys thereof. The VM TSV 204 may have a rectangular shape or a circular shape in the horizontal plane. In addition, the VM TSV 204 may have a dimension (i.e., a diameter) in the horizontal plane ranging from 1 um to 10 um. The VM TSV 204 may have a height ranging from 20 um to 100 um.

In some embodiments, the BEOL structure 206 including metallization layers and dielectric isolation layers can be formed on the frontside of the interface substrate 202 once the VM TSV 204 is completed. The BEOL structure 206 may include metallic materials (e.g., copper and/or aluminum) and dielectric materials (e.g., silicon oxide, and/or silicon nitride). Individual devices such as logic circuits and peripheral circuits disposed on the frontside of the interface substrate 202 can be electrically connected to the BEOL structure 206.

FIG. 2C illustrates a cross-sectional view of the semiconductor wafer 200 after a probe pad 208, a plurality of conductive lines 209, airgaps 212, and a dielectric layer 210 are formed above the BEOL structure 206 and on the frontside of the interface substrate 202. The probe pad 208 and the plurality of conductive lines 209 may have a thickness ranging from 200 nm to 1 um and are formed from a suitable conductive metal such as copper, aluminum, tungsten, cobalt, nickel, or any other suitable conductive materials using an additive process, including but not limited to, plating, depositing, or any other suitable method of manufacturing. After the probe pad 208 and the plurality of conductive lines 209 have been formed, the dielectric layer 210 may be fabricated above the BEOL structure 206 to encapsulate the probe pad 208 and the plurality of conductive lines 209. The dielectric layer 210 may have a thickness ranging from 1 um to 5 um and be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. In addition, the dielectric layer 210 may be processed by a deposition technique at temperatures equal to or higher than 300° C. Depending on dimensions and pitches of the plurality of conductive lines 209, one or more airgaps 212 may be present in the dielectric layer 210.

FIG. 2D illustrates a cross-sectional view of the semiconductor wafer 200 after a carrier wafer 216 is attached to the frontside of the semiconductor wafer 200. In some embodiments and before attaching the carrier wafer 216, the dielectric layer 210 maybe planarized by a CMP process. The planarization process may cause a mechanically altered surface of the dielectric layer 210, including a dishing with a dishing thickness up to 10 nm. In various embodiments, the mechanically altered surface of the dielectric layer 210 may reveal a zigzag profile, polishing marks, and/or whorls after the CMP process. In some other embodiments, an additional dielectric layer may be further deposited on the polished dielectric layer 210 and planarized by the CMP process. The additional dielectric layer may be made of a same material as the dielectric layer 210. In this embodiment, the frontside surface of the semiconductor wafer 200 can be planarized after the second CMP process and retains the mechanically altered surface profile of the dielectric layer 210.

In some embodiments, an interface layer 214 may be deposited on the carrier wafer 216 at a temperature close to 350° C. The interface layer 214 can be made of materials such as silicon oxide, silicon carbon nitride (SiCN), silicon boron carbonitride (SiBCN), or any combination thereof. In addition, the interface layer 214 may be further planarized and have a thickness ranging from 50 nm to 300 nm.

After forming the interface layer 214, the semiconductor wafer 200 can be temporarily attached to the carrier wafer 216 through fusion bonding by facing the frontside of the semiconductor wafer 200 to the interface layer 214 of the carrier substrate 216. Here, chemical bonds (e.g., covalent bonding between SiO—Si or SiCN—Si) can be formed between the surfaces of the interface layer 214 and the dielectric layer 210 to securely hold the layers together. In this example, the fusion bonding between the interface layer 214 and the dielectric layer 210 may be formed at a temperature close to 300° C. or above and/or with compression pressures. Moreover, the carrier wafer 216 can be made of silicon.

FIG. 2E illustrates a cross-sectional view of the semiconductor wafer 200 after a stack of dielectric layers 220, 222, and 224 are formed on the backside surface of the interface substrate 202. In some embodiments, a back grinding process or a CMP process may be performed on the backside surface of the interface substrate 202, to expose the TSV 204 therefrom. As shown in FIG. 2E, a portion of the TSV 204 may be protruded from the backside surface of the interface substrate 202, and a dielectric layer 218 can be formed to cover the backside of the interface substrate 202. The dielectric layer 218 may be deposited at a temperature ranging from 200° C. to 400° C. In addition, the dielectric layer 218 may be made of silicon nitride and have a thickness ranging from 500 nm to 5 um. The dielectric layer 218 may be further planarized by a CMP process to have a surface on a same level to that of the TSV 204.

Subsequently, dielectric layers 220, 222, and 224 can be deposited on the dielectric layer 218. All of the dielectric layers 220, 222, and 224 can be processed at a high temperature around 300° C. or above. Specifically, the dielectric layers 220 and 224 can be made of SiCN and the dielectric layer 222 can be made of silicon oxide. In this example, the dielectric layers 220, 222, and 224 may have a thickness around 150 nm, 1.5 um, and 100 nm, respectively.

As shown in FIG. 2E, bond pads 226 can be formed within the dielectric layers 220, 222, and 224. Each of the bond pads 226 may include a conductive liner (e.g., TaN) and a metal filler (e.g., copper). The bond pads 226 may have a thickness ranging from 1 um to 3 um and a pitch distance around 10 um. As shown, one of the bond pads 226 and the TSV 204 may be connected to each other and include a same liner material and a same metal filler material. Specifically, the one of the bond pads 226 can be electrically coupled to the BEOL structure through the TSV 204.

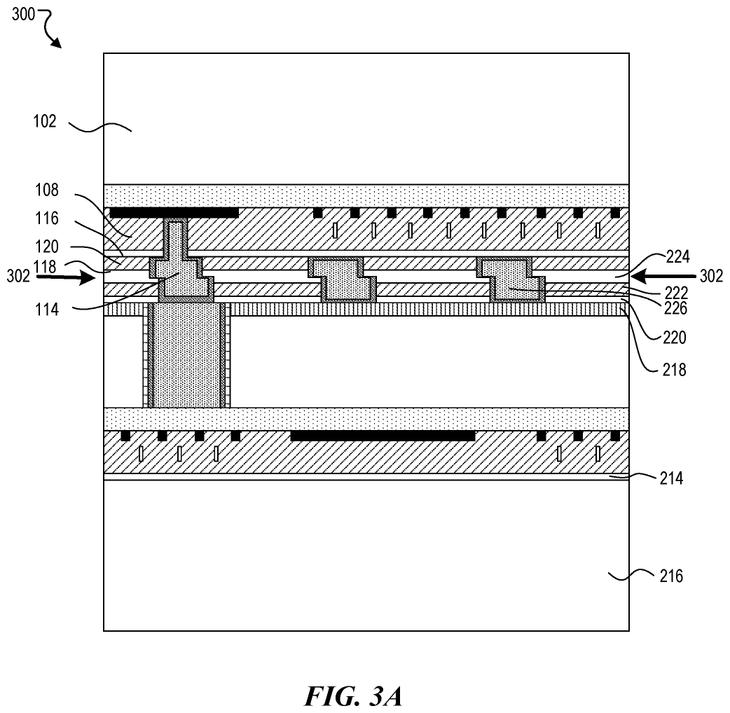

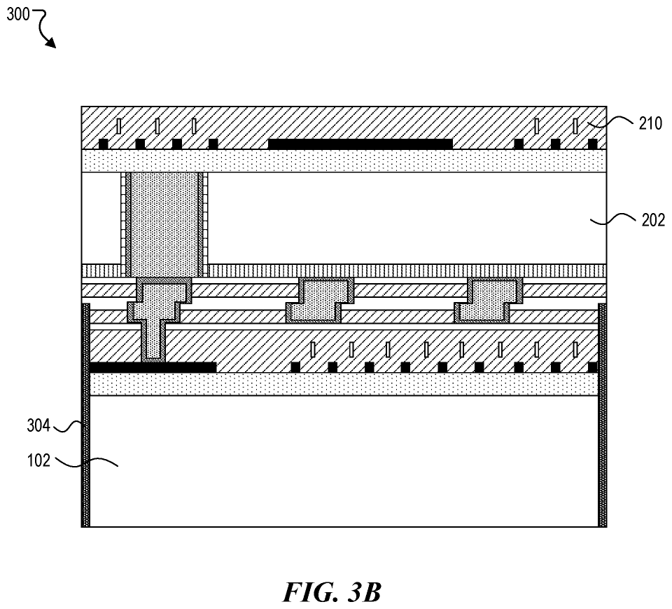

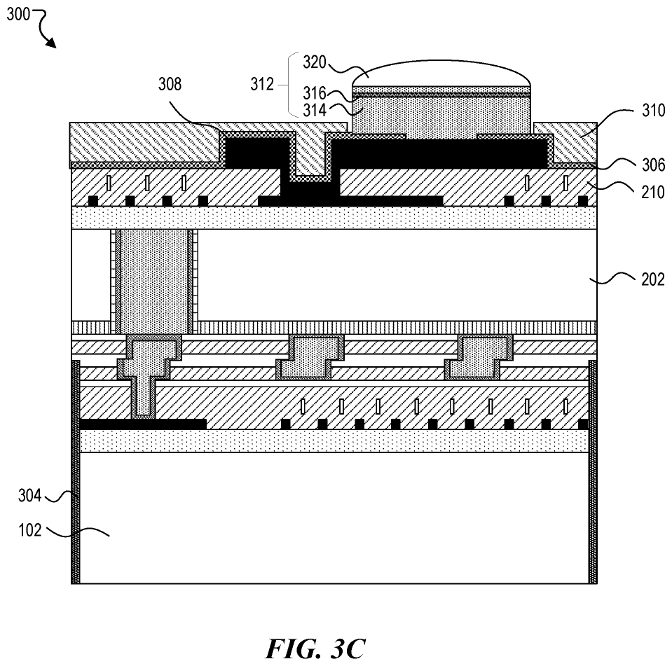

Turning to FIGS. 3A through 3C, which illustrate stages of a process for forming a semiconductor die assembly 300 in accordance with embodiments of the present technology. Particularly, the semiconductor die assembly 300 reveals a C2 W assembly and a F2B direct bonding schemes. For example, FIG. 3A illustrates that the semiconductor die 100 is attached to the semiconductor wafer 200 through the C2 W bonding at a bonding interface 302. It can be found that both of the semiconductor die 100 and the semiconductor wafer 200 are flipped upside down for the C2 W F2B bonding. As shown, the frontside surface of the semiconductor die 100 is bonded with the backside surface of the semiconductor wafer 200. In particular, the semiconductor die assembly 300 may include a hybrid bond at the bonding interface 302, which includes dielectric-dielectric bonds between the dielectric layer 118 and the dielectric layer 224, and metal-metal bonds between the bond pads 114 and the bond pads 226.

In some embodiments, the frontside surface of the semiconductor die 100 and the backside surface of the semiconductor wafer 200 may be treated with a plasma process to facilitate bonding between the dielectric layers 118 and 224, and metal pads 114 and 226. The hybrid bond at the bonding interface 302 may be formed by applying heat at a temperature of 300° C. and above, and/or applying compression pressure. In this example, the metal-metal bonds may be Cu—Cu diffusion bonds between the bond pads 114 and 226 without any gaps therebetween. Moreover, the dielectric-dielectric bonds may be SiCN—SiCN bonds (e.g., strong covalent bonds) between the dielectric layers 118 and 224 without any gaps or voids. As described, the dielectric layers 118 and 224 can be formed in a high temperature process close to 300° C. or above. In the present technology, the high temperature processed dielectric layers 118 and 224 are utilized in achieving dielectric-dielectric bonds with higher bond strength, e.g., having a bond energy close to or higher than 2 J/m², higher than conventional dielectric-dielectric bonds from low temperature processed dielectric layers. As shown in FIG. 3A, by applying heat and/or compression force to the semiconductor die assembly 300, the dielectric layers 118 and 224 can be fused together.

In some other embodiments, the surface of the bond pads 114 and 226 may not be completely joined together (e.g., cojoined) due to the recess in the surfaces of the bond pads. For example, there may be gaps formed at the bonding interface 302 and between the bond pads 114 and 226. Here, the C2 W bonding scheme of the semiconductor die assembly 300 may further include a post bonding thermal annealing step (e.g., at approximately 350° C. for approximately 2 hours or so). During the thermal annealing step, the metal of the bond pads 114 and 226 (e.g., copper) expand toward each other due to the mismatch in coefficient of thermal expansion (CTE) between the metal material and dielectric materials at the bonding interface 302. When the surfaces of the top and bottom bond pads 114 and 226 are in contact, the metals are conjoined (e.g., via atomic migration (or intermixing) from one metal to another metal) to form permanent bonding—e.g., metallurgical bonding. Accordingly and as shown in FIG. 3A, the metals (e.g., copper) of the bond pads 114 and 226 form a contiguous metal structure (e.g., without the gap across the bonding interface 450—e.g., after the thermal annealing step) at the bonding interface 302. The hybrid bonds included in the semiconductor die assembly 300 help semiconductor die manufacturing meet demands for a reduction in volume occupied by semiconductor die assemblies.

In some other embodiments, the frontside surface of the semiconductor die 100 and the frontside surface of the semiconductor wafer 200 may be attached by a hybrid bond. For example, the metal pads 226 maybe fabricated on the frontside surface of the semiconductor wafer 200. Correspondingly, the carrier wafer 216 may be attached to the backside surface of the semiconductor wafer 200. In this example, hybrid bond including metal-metal bonds and dielectric-dielectric bonds may be formed between the frontside surface of the semiconductor die 100 and the frontside of the semiconductor wafer 200.

FIG. 3B illustrates a cross-sectional view of the semiconductor die assembly 300 after flipping it upside down and removing the carrier wafer 216 from the semiconductor wafer 200. As shown and to provide protection for the semiconductor die 100 in the semiconductor die assembly 300, encapsulation material 304 may be applied to the edges of the semiconductor die 100 during a molding process. Here, the carrier wafer 216 may be removed using a grinding process step. In addition, the grinding process may also remove the interface layer 214 and stops on the dielectric layer 210. As described earlier, the dielectric layer 210 may have a mechanical altered surface including a dishing profile or a zigzag feature formed in the grinding process before bonding with the carrier wafer 216. Here, the mechanical altered surface of the dielectric layer 210 may be retained after removing the carrier wafer 216.

FIG. 3C illustrates a cross-sectional view of the semiconductor die assembly 300 including the semiconductor die 100 and the interface die 200, after forming the RDL layer 308 and micro bump 312. In this step, the dielectric layer 210 may be patterned and the RDL layer 308 may be deposited within and above the dielectric layer 308 in order to route electrical signals between the semiconductor die 100 and higher-level circuitry (e.g., a host device external to the logic dies and/or the memory dies). In some embodiments, the RDL layer 308 may be processed by a damascene interconnect process, a plating process, a spin-on deposition process, and/or a polymer-based deposition process. In addition, the RDL layer 308 may have a thickness above the dielectric layer 210 ranging from 1 um to 10 um and may be made of aluminum. Further, a passivation layer 306 may be formed above the RDL layer 308 to provide electrical isolation. The passivation layer 306 may be processed at a temperature ranging from 200° C. to 400° C. and have a thickness ranging from 500 nm to 1 um.

Subsequently, a polyimide layer 310 can be deposited above the passivation layer 306. The polyimide layer 310 can be made of organic polymer materials that exhibit high level of heat resistance, excellent mechanical properties and electrical insulation above the RDL layer 308. Here, the polyimide layer 310 can be processed at a temperature ranging from 200° C. up to 400° C., and have a thickness ranging from 1 um to 5 um.

As shown in FIG. 3C, the polyimide layer 310 and the passivation layer 306 can be patterned to expose at least a portion of the RDL layer 310. A micro bump 312 can be further formed in the patterned region above the exposed RDL layer 310 for I/O electrical connections. In some embodiments, the micro bump 312 may include a cooper pillar 314, a nickel diffusion barrier 316, and a tin-silver solder cap 320. The micro bump 312 can also be referred as copper micro bump/pillar or C2 bump. The ingredients of the micro bump 312 may have a diameter ranging from 10 um to 50 um in the horizontal direction. In addition, the cooper pillar 314 may have a height around 15 um. The nickel diffusion barrier 316 may have a thickness of 3 um. The tin-silver solder cap may have a thickness around 18 um. In other embodiments, the micro bump 312 may also include an under-bump-metallurgy (UBM) layer (not shown) between the copper pillar 314 and the exposed RDL layer 308. The UBM layer may include a titanium portion having a thickness around 150 nm and a cooper portion having a thickness around 200 nm. In this example, the semiconductor die assembly 300 may be completed by singulating the semiconductor wafer 200 to interface dies.

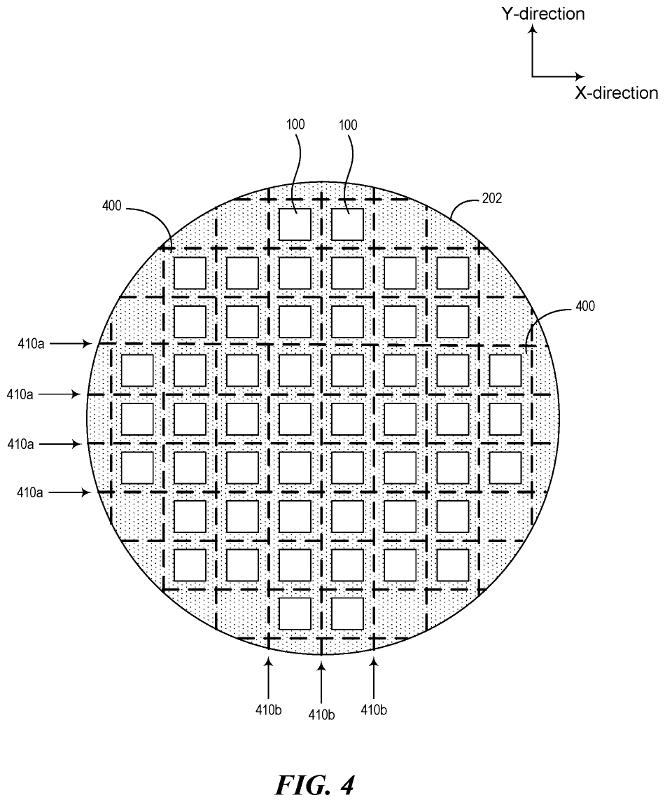

FIG. 4 depicts a diagram of the semiconductor wafer 200 assembled with semiconductor dies 100 in accordance with embodiments of the present technology. The interface substrate 202 carrying the semiconductor dies or stacks of semiconductor dies 100 may be referred to as CoW assembly in view of the singulated, individual semiconductor dies 100 (or stacks of semiconductor dies) that are aligned and attached to corresponding interface die 400. Although the present technology is described herein with semiconductor device assemblies including semiconductor dies or a stack of semiconductor dies attached to a semiconductor wafer (e.g., the semiconductor wafer 200), it should be understood that the principles of the present technology are not limited thereto. For example, a semiconductor device assembly in accordance with the present technology may include a single semiconductor die (e.g., a memory die) attached (or bonded) to an interface die.

In some embodiments, the semiconductor wafer 200 are different types of semiconductor dies (e.g., logic dies, controller dies) than the semiconductor dies 100 (e.g., memory dies, DRAM products) of the stacks. The logic dies can be configured to exchange electrical signals with the semiconductor dies 100 and with higher level circuitry (e.g., a host device external to the semiconductor device assembly) coupled with the logic dies. In some embodiments, the semiconductor wafer 200 are interposer dies having various conductive structures (e.g., redistribution layers, vias, interconnects) configured to route electrical signals between the semiconductor dies 100 and higher-level circuitry—e.g., a central processing unit (CPU) coupled with the semiconductor dies 100 through the interposer die.

In some embodiments, each of the semiconductor dies 100 may include semiconductor dies stacked on top of each other. Each semiconductor die of the stack has a frontside facing toward the semiconductor wafer 200, which may be referred to as an active side of the semiconductor die having memory arrays, integrated circuits coupled to the memory arrays, bond pads coupled to the integrated circuits, etc., and a backside opposite to the frontside. As described in more detail herein, the backside of semiconductor dies 100 may include bond pads configured to attach to (or bond to) bond pads of another die (or wafer). Further, the semiconductor dies 100 may include TSVs extending through the semiconductor dies 100 and configured to couple the bond pads on the frontside with the bond pads on the backside. The uppermost semiconductor dies 100 of the stack may be referred to as a top die, and one or more semiconductor dies 100 located between the top die and the interface die 106 may be referred to as core dies. Subsequently, the core dies can be diced and stacked on the semiconductor wafer 200 along with the top die (e.g., using process steps for direct bonding) to generate the reconstituted wafer as illustrated in FIG. 1. The top dies of the stack of semiconductor dies 100, however, may be thicker than the core dies and may not have backside conductive structures (or TSVs).

The process steps used for preparing semiconductor dies for stacking them on top of each other (e.g., forming bond pads and/or conductive structures coupled to integrated circuits on the frontside of the wafer, temporarily attaching the wafer to a carrier substrate, thinning the wafer from the backside, forming the conductive pads on the backside, etc.) can be applied to the interface substrate 202 such that appropriate conductive structures for stacking semiconductor dies can be formed on the frontside and backside of the interface dies 200. As such, the interface substrate 202 may correspond to the semiconductor wafer having completed the process steps described above—e.g., having been thinned and including appropriate conductive structures for stacking on the frontside and backside. FIG. 4 also depicts scribe lines 410 (which may be referred to as dicing lanes, cutting lines, or the like) of the interface substrate 202 (e.g., horizontal scribe lines 410a along the x-direction and vertical scribe lines 410b along the y-direction) between the stacks of semiconductor dies 100. In some embodiments, after completing the molding process for the CoW assembly, individual semiconductor die assemblies are singulated along the scribe lines.

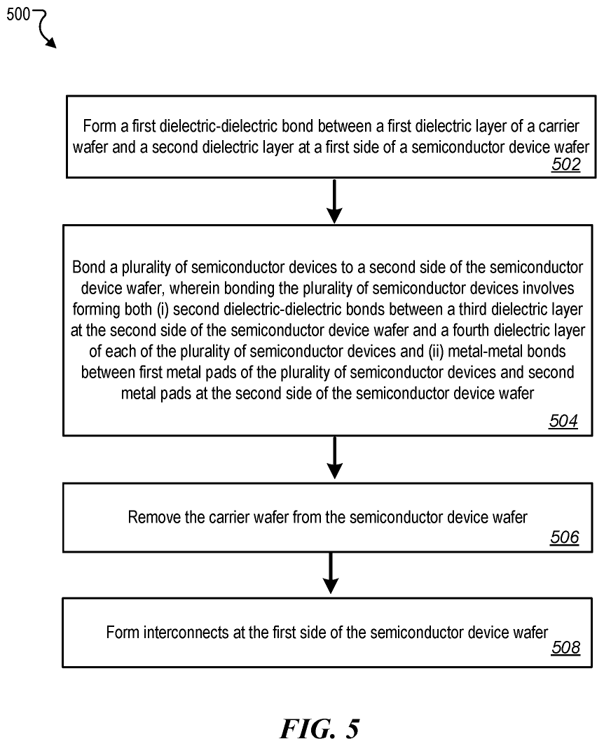

FIG. 5 is a flow chart illustrating a method 500 of processing semiconductor devices assemblies according to embodiments of the present technology. The method 500 includes forming a first dielectric-dielectric bond between a first dielectric layer of a carrier wafer and a second dielectric layer at a first side of a semiconductor device wafer, at 502. For example, the carrier wafer 216 can be attached to the frontside surface of the semiconductor wafer 200 through dielectric-dielectric bonds. Specifically, the interface layer 214 disposed above the carrier wafer 216 can be attached to the dielectric layer 210 of the semiconductor wafer 200 through fusion bonding technologies. The fusion bonding technologies may form chemical bonds (e.g., covalent bonding between SiO—Si or SiCN—Si) between the interface layer 214 and the dielectric layer 210. In addition, the semiconductor wafer 200 may be an ultra-thin logic wafer having a thickness close to or less than 50 um so as to assist manufacturing a low-profile semiconductor device assembly.

The method 500 also includes bonding a plurality of semiconductor devices to a second side of the semiconductor device wafer, wherein bonding the plurality of semiconductor devices involves forming both (i) second dielectric-dielectric bonds between a third dielectric layer at the second side of the semiconductor device wafer and a fourth dielectric layer of each of the plurality of semiconductor devices and (ii) metal-metal bonds between first metal pads of the plurality of semiconductor devices and second metal pads at the second side of the semiconductor device wafer, at 504. For example, the semiconductor dies 100 can be attached to the semiconductor wafer 200 through a C2 W hybrid bond on the bonding interface 302. As shown in FIG. 3A, the hybrid bond interface 302 includes dielectric-dielectric bonds between the dielectric layer 118 of the semiconductor dies 100 and the dielectric layer 224 of the semiconductor wafer 200. Specifically, the dielectric-dielectric bonds can be gap free SiCN—SiCN covalent bonds processed at a temperature close to or higher than 300° C. The hybrid bond interface 302 may also include metal-metal bonds between the metal pads 114 of the semiconductor dies 100 and the metal pads 226 of the semiconductor wafer 200. In this example, the metal-metal bonds can be gap free Cu—Cu diffusion bonds processed at a temperature close to or higher than 350° C.

Further, the method 500 includes removing the carrier wafer from the semiconductor device wafer, at 506. For example, the carrier wafer 216 as well as the interface layer 214 can be removed from the semiconductor wafer 200 by the CMP process. The CMP process may stop at the dielectric layer 210 of the semiconductor wafer 200 and retains a mechanically altered surface thereon.

Lastly, the method 500 includes forming interconnects at the first side of the semiconductor device wafer, at 508. For example, as shown in FIG. 3C, the RDL layer 308 can be formed on the dielectric layer 308 of the semiconductor die assembly 300. In addition, the micro bump 312 can be formed on a patterned region above the RDL layer 308 for electrical connections of the semiconductor dies 100 and the semiconductor wafer 200.

One or more of the manufacturing steps of method 500 described above could be performed by more than one entity. For example, the semiconductor device wafer may be manufactured by entity A and the plurality of semiconductor devices may be manufactured by entity B.

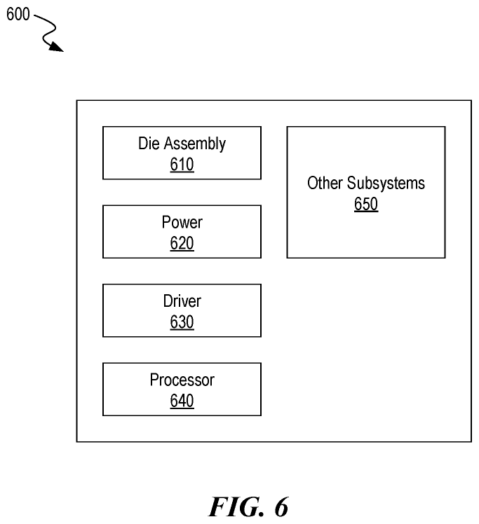

Any one of the semiconductor structures described above with reference to FIGS. 1A-3C can be incorporated into any of a myriad of larger and/or more complex systems, a representative example of which is system 600 shown schematically in FIG. 6. The system 600 can include a semiconductor device 610, a power source 620, a driver 630, a processor 640, and/or other subsystems or components 650. The semiconductor device 610 can include features generally similar to those of the semiconductor devices described above, and can therefore include the CoW assemblies described in the present technology. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, and appliances. Components of the system 600 may be housed in a single unit or distributed over multiple, interconnected units (e.g., through a communications network). The components of the system 800 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present technology, the semiconductor device assembly described above could include a semiconductor memory device and a logic interface wafer. The semiconductor device assembly may further include one or more high-temperature (HT) processed dielectric layers (e.g., HT SiCN, HT SiO, and/or HT SiN) and one or more bond pads (e.g., Cu—Cu pads) that are sandwiched between the semiconductor memory device and the logic interface wafer. The HT processed dielectric layers and the bond pads can be formed at temperatures close to or above 300° C.

In accordance with another aspect of the present technology, the semiconductor device assembly described above could include a semiconductor memory device and a logic interface wafer having a backside surface. The backside surface of the logic interface wafer may include one or more HT processed dielectric layers (e.g., HT SiCN, HT SiO, and/or HT SiN). Specifically, the semiconductor memory device and the logic interface wafer are coupled/bonded through various bond pads (e.g., Cu—Cu pads).

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a semiconductor die having a frontside surface, a first plurality of bond pads at the frontside surface and a first dielectric layer at the frontside surface; and
an interface die having a frontside surface and a backside surface, the interface die including:
a second plurality of bond pads and a second dielectric layer disposed on the backside surface of the interface die,
a third dielectric layer disposed on the frontside surface of the interface die, wherein the third dielectric layer includes a mechanically altered surface opposite the frontside surface of the interface die, and
a redistribution layer disposed on the third dielectric layer and above the frontside surface of the interface die,
wherein hybrid bonds are disposed between the frontside surface of the semiconductor die and the backside surface of the interface die.

2. The semiconductor device assembly of claim 1, wherein the hybrid bonds include a metal-metal bond and a dielectric-dielectric bond.

3. The semiconductor device assembly of claim 2, wherein the plurality of bond pads of the semiconductor die and the interface die are made of materials including at least one of copper, silver, gold, nickel, tungsten, or a combination thereof.

4. The semiconductor device assembly of claim 2, wherein the metal-metal bond is a diffusion bond formed between the first plurality of bond pads of the semiconductor die and the second plurality of bond pads of the interface die, and wherein the metal-metal bond is gap free.

5. The semiconductor device assembly of claim 2, wherein the dielectric-dielectric bond is a covalent bond formed between the first dielectric layer of the semiconductor die and the second dielectric layer of the interface die, and wherein the dielectric-dielectric bond is gap free.

6. The semiconductor device assembly of claim 5, wherein the first and the second dielectric layers are made of at least one of tetraethyl orthosilicate, silicon oxide, silicon nitride, silicon borocarbonitride, silicon oxycarbonitride, silicon oxycarbide, silicon carbonitride, silicon boronitride, a low-k dielectric material, or a combination thereof.

7. The semiconductor device assembly of claim 1, further comprising a micro bump electrically connected to the redistribution layer of the interface die and disposed on the front surface of the interface die.

8. The semiconductor device assembly of claim 1, further comprising a molding compound encapsulating the semiconductor die, wherein the molding compound comprises at least one of an epoxy-based liquid compound with granules, an epoxy-based liquid compound without granules, a granular compound, a thin-film based underfill, a thin-film based compound, a resin-based encapsulant, or a polymer.

9. The semiconductor device assembly of claim 1, further comprising a polyimide layer disposed on the front surface of the interface die, the polyimide layer encapsulating the third dielectric layer and the redistribution layer of the interface die.

10. The semiconductor device assembly of claim 1, wherein the mechanically altered surface of the third dielectric layer includes a dishing, zigzag profiles, polishing marks, and/or whorls.

11. A semiconductor device assembly, comprising:
a semiconductor die having a first side, a first plurality of bond pads, and a first dielectric layer at the first side; and
an interface die having a first side and a second side, the interface die including:
a second plurality of bond pads and a second dielectric layer disposed on the first side of the interface die, and
a third dielectric layer disposed on the second side of the interface die, wherein the third dielectric layer includes a plurality of polishing marks opposite the first side of the interface die,
wherein hybrid bonds are disposed between the first side of the semiconductor die and the first side of the interface die.

12. The semiconductor device assembly of claim 11, wherein the hybrid bonds include gap free metal-metal diffusion bond between the first and the second plurality of bond pads, and gap free dielectric-dielectric covalent bond between the first dielectric layer of the semiconductor die and the second dielectric layer of the interface die.

13. A method of forming a semiconductor assembly, comprising:
forming a first dielectric-dielectric bond between a first dielectric layer of a carrier wafer and a second dielectric layer at a first side of a semiconductor device wafer;
bonding a plurality of semiconductor devices to a second side of the semiconductor device wafer, wherein bonding the plurality of semiconductor devices involves forming both (i) second dielectric-dielectric bonds between a third dielectric layer at the second side of the semiconductor device wafer and a fourth dielectric layer of each of the plurality of semiconductor devices and (ii) metal-metal bonds between first metal pads of the plurality of semiconductor devices and second metal pads at the second side of the semiconductor device wafer, wherein the third dielectric layer at the second side of the semiconductor device wafer is formed in a high temperature process at 300° C. or above;
removing the carrier wafer from the semiconductor device wafer; and
forming interconnects at the first side of the semiconductor device wafer.

14. The method of forming the semiconductor assembly of claim 13, wherein forming the first dielectric-dielectric bond includes grinding the second dielectric layer at the first side of the semiconductor device wafer by a chemical mechanically polishing (CMP) process, the CMP process forming a mechanically altered surface on the second dielectric layer of the semiconductor device wafer, and wherein the mechanically altered surface of the second dielectric layer includes a dishing or zigzag profile.

15. The method of forming the semiconductor assembly of claim 14, wherein forming the first dielectric-dielectric bond further includes:
coating a fifth dielectric layer above the mechanically altered surface of the second dielectric layer of the semiconductor device wafer, and
planarizing the fifth dielectric layer by the CMP process at the frontside of the semiconductor device wafer.

16. The method of forming the semiconductor assembly of claim 15, wherein forming interconnects at the first side of the semiconductor device wafer includes forming a redistribution layer and a micro bump above the first side of the semiconductor device wafer.

17. The method of forming the semiconductor assembly of claim 16, further includes forming a polyimide layer encapsulating the redistribution layer and the fifth dielectric layer of the semiconductor device wafer, the polyimide layer being processed at a temperature ranging from 200° C. to 400° C.

18. The method of forming the semiconductor assembly of claim 13, wherein the first dielectric-dielectric bond is a gap free covalent bond processed at a temperature close to or higher than 300° C., and wherein the first and the second dielectric layers are made of at least one of tetraethyl orthosilicate, silicon oxide, silicon nitride, silicon borocarbonitride, silicon oxycarbonitride, silicon oxycarbide, silicon carbonitride, silicon boronitride, a low-k dielectric material, or a combination thereof.

19. The method of forming the semiconductor assembly of claim 13, wherein the second dielectric-dielectric bonds are gap free covalent bonds processed at a temperature close to or higher than 300ºC, and wherein the third and the fourth dielectric layers are made of at least one of tetraethyl orthosilicate, silicon oxide, silicon nitride, silicon borocarbonitride, silicon oxycarbonitride, silicon oxycarbide, silicon carbonitride, silicon boronitride, a low-k dielectric material, or a combination thereof.

20. The method of forming the semiconductor assembly of claim 13, wherein the metal-metal bonds are gap free diffusion bonds processed at a temperature close to or higher than 350° C.
